(19) United States
(12) Patent Application Publication
(10) Pub. No.: US 2025/0065722 A1
(43) Pub. Date: Feb. 27, 2025

(54) High-Voltage Vehicle Electrical System With Potential Island In Two-Stage Insulation And With Resistance Dissipation

(71) Applicant: Vitesco Technologies GmbH, Regensburg (DE)

(72) Inventors: Franz Pfeilschifter, Walderbach (DE); Tobias Steckermeier, Pettendorf (DE); Michael Kunz, Regenstauf-Loch (DE)

(73) Assignee: Vitesco Technologies GmbH, Regensburg (DE)

(21) Appl. No.: 18/944,406

(22) Filed: Nov. 12, 2024

Related U.S. Application Data
(63) Continuation of application No. PCT/EP2023/061144, filed on Apr. 27, 2023.

(30) Foreign Application Priority Data
May 12, 2022 (DE) 10 2022 204 641.2

(51) Int. Cl. B60L 3/00; B60L 53/10

(52) U.S. Cl. CPC B60L 3/0046; B60L 53/11; B60L 2240/549

(57) ABSTRACT

A high-voltage vehicle on-board electrical system is equipped with a ground potential and a high-voltage potential that is insulated from the ground potential by a two-stage insulation. The two-stage insulation has a first insulation device that insulates the high-voltage potential from a potential island. A second insulation device of the two-stage insulation insulates the potential island from the ground potential. The potential island is connected to the ground potential via a dissipating element. The dissipating element is configured, in the event of an insulation fault in the two-stage insulation, to generate a current that is below a hazard threshold and that is above a sensitivity threshold of an insulation monitor.

### CROSS-REFERENCE TO RELATED APPLICATIONS

This application claims the benefit of PCT Application PCT/EP2023/061144, filed Apr. 27, 2023, which claims priority to German Application 10 2022 204 641.2, filed May 12, 2022. The disclosures of the above applications are incorporated herein by reference.

### TECHNICAL FIELD

The disclosure relates to a high-voltage vehicle electrical system with potential island in two-stage insulation and with resistance dissipation.

### BACKGROUND

Vehicles are equipped with an electrical traction drive, where a high-voltage on-board electrical system is used to transmit energy. This high-voltage on-board electrical system operates at high voltages in order to be able to meet the high-power requirements during traction.

For example, when charging with DC voltage, high voltages are used, in some cases up to 800 V or even more. These high voltages may pose a high risk. In order to avoid a hazard due to contact voltage, the high-voltage potentials are insulated from the ground potential of the vehicle (chassis etc.).

If double or reinforced insulation is to be provided between the high-voltage region and the low-voltage region (with reference to ground), then a high-voltage potential is insulated by way of a first insulation device, followed by a second insulation device, to provide two-stage insulation from the ground potential. In some examples, a first optocoupler with an input-side high-voltage potential and a second optocoupler with an output-side ground reference may be connected in series in a transmission chain, as a result of which double insulation between the high-voltage potential and the ground potential is produced. It may be determined that an insulation fault in one of these insulation stages is not detected because the other insulation stage prevents the current flow that would be necessary to record insulation faults.

### SUMMARY

The disclosure provides a high-voltage vehicle on-board electrical system. The disclosure describes insulating a high-voltage potential from a ground potential in a two-stage manner by way of two successive insulation devices. There is a (conductive) potential island between the insulation devices. The insulation devices are connected via the potential island. In order to make it possible to detect an insulation fault in one of the insulation devices, the potential island is connected to a ground potential (or the above-mentioned high-voltage potential or a further high-voltage potential) of the vehicle on-board electrical system via a dissipating element. If there is then a fault in the first insulation device, a current flow results via the dissipating element, the current flow is able to be recorded by an insulation monitor. At the same time, the dissipating element makes it possible to prevent an excessively high contact current from arising due to the defective first insulation device, where the resistor limits the contact current to a harmless level.

Implementations of the disclosure may include one or more of the following optional features. In some implementations, a high-voltage vehicle on-board electrical system (referred to below, for short, as: on-board electrical system) with a ground potential and a high-voltage potential is therefore described. Multiple high-voltage potentials may also be provided in the on-board electrical system, which are insulated from ground as described here. The high-voltage potential is insulated from the ground potential by way of two-stage insulation. This insulation may correspond to double or reinforced insulation (provided the reinforced insulation has two stages). The two-stage insulation has a first insulation device. The first insulation device insulates the high-voltage potential from a potential island. The insulation device extends between a conductor at which the high-voltage potential is present and the potential island. A second insulation device of the two-stage insulation insulates the potential island from the ground potential. In this case, the ground potential may correspond to the potential of the chassis or the vehicle ground or to a potential that is connected galvanically thereto. The potential of the potential island may be an indicator of the fault-free functioning of the insulation devices. In other words, the potential of the potential island may be used to record faults in the two-stage insulation or in the insulation devices. The potential island may therefore be a voltage sensor or potential sensor in the middle between the two insulation devices. In order to be able to record the state of the insulation, the potential of the potential island is evaluated. In some examples, a dissipating element is used in this case, which connects the potential island to the ground potential (or another potential that is connected galvanically thereto). (Alternatively, the dissipating element may connect the potential island to the high-voltage potential or to another high-voltage potential of the on-board electrical system to record an insulation fault in the second insulation device).

The dissipating element generates a current flow if the potential island is not correctly insulated from the high-voltage potential, with the result that this current flow is used as a signal for faulty two-stage insulation. The dissipating element is designed in such a way that it generates a current, the magnitude of which is sufficient to be detected by an insulation monitor. Furthermore, the dissipating element is dimensioned in such a way that, in the event of a fault in the two-stage insulation, no hazardous contact current, or only a contact current that is below a hazard threshold, for example, by a predetermined safety margin, is produced. The potential island is therefore connected to the ground potential via the dissipating element, which is configured, in the event of an insulation fault in the first or the second insulation device, to generate a current that is below a hazard threshold and that is simultaneously above a sensitivity threshold of an insulation monitor.

In some implementations, the dissipating element includes a resistor. Examples that are described based on a resistor as a dissipating element may be generally embodied as shown with a dissipating element, as is shown below. For the sake of simplification, in the text that follows, and in the description of the figures and in the title, the term “dissipating element” is also referred to as “resistor”. The dissipating element may include one or more resistor components that are connected to one another. The dissipating element may also be or contain an ohmic component, a capacitive component and/or an inductive component. The dissipating element may also be formed by a high-pass filter, a low-pass filter or a band-pass filter, which may additionally have an ohmic component. The dissipating element may therefore be designed to be frequency-selective in order to produce a certain frequency-dependent transmission behavior, for instance depending on the application or depending on the signals that arise (or that are to be expected) due to an insulation fault. Instead of, or in combination with, linear components, the dissipating element may have at least one non-linear component, such as a component having a real impedance that depends on the voltage present at the component, for example a Zener diode, a varistor, a gas discharge tube, a spark gap, a protective diode, a thyristor circuit, a DIAC, and/or a four-layer diode. The dissipating element may therefore be designed to generate a current flow that is detected by an insulation monitor only from a certain signal strength or voltage. This avoids false-positive detection of insulation faults.

The hazard threshold may, for example, result from standards for wired charging for electric vehicles. In the same way, the sensitivity threshold from which an insulation monitor has to react may also be taken from a standard for high-voltage technology. Alternatively or in combination, the hazard threshold may be designed in such a way that a current, a voltage or a power (flowing through the device), which is within the nominal current, the nominal voltage or the nominal power (or nominal pulse power) of the insulation device (or both insulation devices), is produced for the first and/or second insulation device. Alternatively or in combination with the above definition, the hazard threshold may therefore be designed in such a way that the insulation devices, in the event of an insulation fault (in one of the devices), the other insulation device is not damaged and for example, retains its insulation properties or its insulation resistance. This ensures that, as a result of the current that is generated by the resistor in the event of an insulation fault, the fault-free insulation device maintains its insulating property. In other words, the resistor is designed in such a way that a current flow through the resistor does not cause the fault-free insulation device to be damaged or the insulation resistance of this insulation device to not (significantly) decrease. A consequential fault (in the other insulation device) resulting from an insulation fault in an insulation device is avoided due to the value of the resistance or due to the transmission behavior of the dissipating element. The transmission behavior of the dissipating element makes provision for a current flow, which is able to be recorded by the insulation monitor, to be produced via this dissipating element. The transmission behavior of the dissipating element makes provision for a current flow to be produced via this dissipating element, which is above the sensitivity threshold of the insulation monitor or another safety apparatus.

A resistor element provided as a dissipating element may have a value that is at least 75 kOhm, 80 kOhm or 85 kOhm. In combination or alternatively, the resistor element may have a value that is not more than 150 kOhm, 120 kOhm or 100 kOhm. The dissipating element may have a transmission behavior that corresponds to such a resistor element.

The high-voltage vehicle on-board electrical system may be designed for a nominal voltage above 60 V, such as at least 200 V, at least 400 V, or more. In some examples, the high-voltage vehicle on-board electrical system has a nominal voltage of more than 600 V, such as from 650 V to 900 V or more specifically from 700 V to 850 V. The vehicle on-board electrical system may therefore, for example, have a nominal voltage of approximately 800 V, 820 V or 850 V. The addition of “approximately” in this case means a tolerance of not more than 2%, 5% or 10%. The dissipating element may have a transmission behavior that corresponds to such a resistor element.

The reason why a resistor element in the form of a dissipating element generates a current above the sensitivity threshold in the event of an insulation fault is that the resistance value corresponds to the value of 80 kOhm with a deviation of not more than 20% or 10%. This is in particular combined with an on-board electrical system that has a nominal voltage of 800 V. The resistance value may also assume other values at other nominal voltages, where the resistance value is adjusted proportionally to the change factor of the nominal voltage. The dissipating element may have a transmission behavior that corresponds to such a resistor element.

The nominal voltage of the on-board electrical system may also be 400 V. In this case, the reason why the resistor is configured, in the event of an insulation fault, to generate a current above the sensitivity threshold is that the resistance value corresponds to the value of 40 kOhm with a deviation of not more than 20% or 10%. Therefore, at different nominal voltages, the resistance may have a value of 80 kOhm (at nominal voltages of 800 V) or of 40 kOhm (at a nominal voltage of 400 V). These figures have a tolerance of not more than 20% or 10%.

The on-board electrical system may have an insulation monitor. The insulation monitor monitors the insulation of the high-voltage potential from the ground potential. For example, the insulation monitor has a sensitivity threshold that corresponds to the sensitivity threshold that determines the value of the resistance (taking the high voltage into consideration). The sensitivity threshold referred to in relation to the resistance may correspond to the insulation monitor, which is part of the on-board electrical system.

The insulation monitor is connected to the ground potential and the high-voltage potential in order to determine the insulation between them. In this case, the insulation monitor is configured to measure the insulation resistance between the high-voltage potential and the ground potential. This may be done in an active manner by virtue of applying a test voltage and measuring the resulting current, or by virtue of injecting a test current and ascertaining the resulting voltage. The insulation monitor may be configured to relate the test current and the resulting voltage or the test voltage and the resulting current to one another in order to ascertain the insulation resistance. Furthermore, in a simpler example, the insulation monitor may apply a certain test voltage (or index a certain test current) so that the resulting current or the resulting voltage is the quantity on the basis of which the insulation resistance is ascertained directly or indirectly. On account of the dissipating element described here, it is ensured that an insulation fault is recorded only in the first insulation device (when the second insulation device is functioning), since the resistance significantly contributes to the fault detection on account of the operation of the insulation monitor (and on account of the value of the resistance).

In order to selectively direct the load, which results from the pulse voltage, to the first insulation device, Cy capacitances may be connected in parallel with the first insulation device, on the one hand, and the second insulation device, on the other hand. By way of example, the values of the Cy capacitors may be in the range from 100 pF to 2 nF. The capacitances of the Cy capacitors may in each case be at least 100 pF, 500 pF or 700 pF, or else 1 nF or 2 nF. In addition, the capacitance values of the capacitors may not be more than 50 nF, 20 nF, 10 nF, 5 nF or 2 nF. The Cy capacitors form a capacitive voltage divider, the ends of which are connected to the ground potential and the high-voltage potential. The connecting point between the capacitors in the capacitive voltage divider is connected to the potential island. The capacitive voltage divider does not necessarily have a division of 1:1, but may also have a division of 1:2, 1:3, 1:4 or 1:5. For example, in this case, the first capacitor (that connects the potential island to the high-voltage potential) may be greater than the second capacitor, for example by a factor of at least two, three, four or five. In some examples, the capacitance of the first Cy capacitor is, for example, 20 nF and that of the second capacitor is 5 nF. In other examples, the second capacitor may be greater than the first capacitor (where the division may be 2:1, 3:1, 4:1 or 5:1). In some examples, if the resistor connects the potential island to the high-voltage potential, then the second capacitor may be greater than the first capacitor.

In some implementations, the insulation devices are the insulating elements of components that transmit in a galvanically isolating manner, such as transformers or optocouplers. Furthermore, the insulation devices may also be provided by insulation material, for example by a cable insulation or by insulation material of a substrate or a circuit board or by a housing.

The potential island within the on-board electrical system may not be accessible from the outside, but rather is covered, for instance by way of insulation material. Only the connection of the dissipating element leading to the potential island conductively leads away from the potential island, wherein this is preferably the only conductive route for the potential out of the potential island. In some examples, however, this connection and the dissipating element are also not accessible from the outside through an insulating cover. The dissipating element and the potential island (and also the cover) may be covered or enclosed together and therefore not accessible from the outside. Only the discharge line leading away from the dissipating element, i.e. the discharge line between the dissipating element and the ground potential, may be accessible because it carries ground potential. Alternatively, this discharge line between the dissipating element and the ground potential may also be covered by a housing (by way of insulation material).

A vehicle that is equipped with the high-voltage vehicle on-board electrical system may be provided, where a traction drive and/or a vehicle-side high-voltage charging apparatus of the vehicle is part of the on-board electrical system.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 provides an exemplary on-board electrical system.

Like reference symbols in the various drawings indicate like elements.

### DETAILED DESCRIPTION

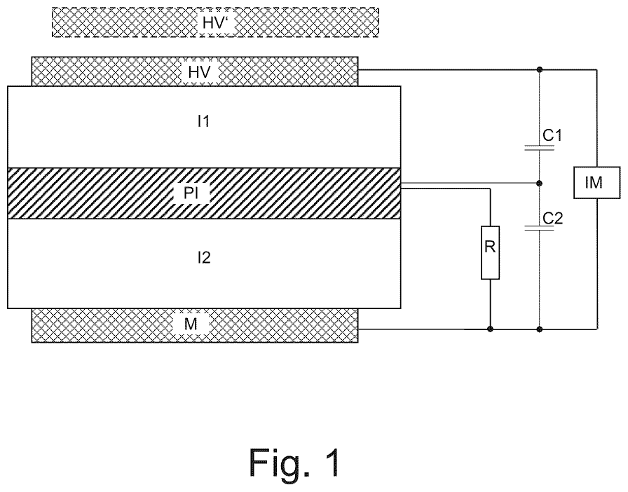

FIG. 1 symbolically shows a high-voltage vehicle on-board electrical system and in particular the high-voltage potential HV thereof and the ground potential M thereof. The high-voltage potential HV shown does not necessarily have to be the only high-voltage potential of the vehicle on-board electrical system, rather, there may be a further high-voltage potential HV′, which is shown merely symbolically. This potential HV′ may be insulated as described here, i.e. insulated in the same way as the high-voltage potential with the reference sign HV. The potential HV may correspond to a positive high-voltage potential and the potential HV′ may correspond to a negative high-voltage potential. The on-board electrical system has a high voltage that is applied between the potentials HV and HV′.

An insulation device I1 insulates the high-voltage potential HV from a potential island PI. The potential island PI itself is conductive, as is the carrier of the high-voltage potential HV.

A second insulation device I2 insulates the potential island from a ground potential M. The ground potential M may be the chassis potential of a vehicle. As is conventional, the high-voltage potential HV (or as high-voltage potential HV-) is galvanically isolated from the ground potential. The resistor R is provided in order to nevertheless provide a possibility of a fault in the insulation device I1 for an insulation monitor IM.

The resistor R connects the potential island PI to the ground potential M. Generally, the potential island PI is connected to the ground potential M via the resistor, where further elements (diodes, fuses or similar) may also be provided. It is relevant for the resistor to be provided between the potential PI and the potential M in order to therefore cause, in the event of faulty insulation I1, a limited current flow that is great enough to be detected by the insulation monitor IM as an insulation fault.

The insulation monitor IM shown is connected to the high-voltage potential HV and to the ground potential M. If the insulation device I1 is defective, a current flows through the resistor R since the high-voltage potential HV is also present at the potential island PI on account of the insulation fault. This current through the resistor R therefore may be reliably recorded. In the absence of a resistor R, the insulation device I1 could be defective and the potential island P1 could carry the high-voltage potential HV, and yet the insulation monitor IM would not be able to detect an insulation fault because the insulation device I2 between the potential PI and the potential M prevents a current flow that is required to detect the insulation fault.

Furthermore, a capacitive voltage divider with two Cy capacitors C1, C2 is provided. The inner connecting point of the voltage divider, i.e. the connection between C1 and C2, is connected to the potential island P1. The two ends of the voltage divider are connected to the potentials HV and M. The capacitor C1 therefore connects the potential HV to the potential of the potential island PI. The capacitor C2 connects the potential island P1 to the ground potential M. Since the capacitors C1, C2 are present between a ground potential and a high-voltage potential, they are referred to as Cy capacitors.

The capacitors C1, C2 shown are implemented as dedicated capacitor components. The capacitor C1 may be greater than the capacitor C2 in order to therefore selectively direct a voltage pulse load to the insulation device I2, and in order to protect the insulation device I1 more or to subject the insulation device to lower loading. In this way, the capacitive voltage divider may be used to direct the pulse load focused on that insulation device I1, I2 that may be monitored by means of the resistor. If the resistor is provided between the potential island P1 and the potential M, then the insulation device I1 is monitored, with the result that the pulse load is then focused on the insulation device I1. If, in some examples that are not shown, the resistor is between the potential island PI and the high-voltage potential HV, then the pulse load is focused on the insulation device I2. The insulation device that is connected in parallel with the capacitor with the lower capacitance of the two capacitors receives the higher pulse load. In some examples, this is also that one of the two insulation devices that is able to be monitored, i.e., that, in the event of a fault, causes current to flow through the resistor R (that may be detected as an insulation fault by the insulation monitor).

Therefore, if the resistor R connects the potential island PI to the ground potential M, then the capacitor that is provided between the high-voltage potential HV and the potential island PI is the smaller of the two capacitors. If the resistor R is provided between the high-voltage potential HV and the potential island PI, then the capacitor C2 is the smaller of the two capacitors. The capacitor C2 is the one in this case that connects the potential island PI to the ground potential M.

A number of implementations have been described. Nevertheless, it will be understood that various modifications may be made without departing from the spirit and scope of the disclosure. Accordingly, other implementations are within the scope of the following claims.

What is claimed is:

1. A high-voltage vehicle on-board electrical system comprising:
a ground potential;
a two-stage insulation;
a high-voltage potential insulated from the ground potential by the two-stage insulation;
a potential island;
wherein the two-stage insulation comprises:
a first insulation device that insulates the high-voltage potential from the potential island, and
a second insulation device that insulates the potential island from the ground potential, and
wherein the potential island is connected to the ground potential via a dissipating element, that is configured, in an event of an insulation fault in the two-stage insulation, to generate a current that is below a hazard threshold and that is above a sensitivity threshold of an insulation monitor.

2. The high-voltage vehicle on-board electrical system of claim 1, wherein the dissipating element comprises a resistor element that has a value that is at least 75 kOhm, 80 kOhm or 85 kOhm and that is not more than 120 kOhm or 100 kOhm.

3. The high-voltage vehicle on-board electrical system of claim 1, wherein the high-voltage vehicle on-board electrical system has a nominal voltage of 650 V-900 V or 700 V-850 V.

4. The high-voltage vehicle on-board electrical system of claim 1, wherein the dissipating element comprises a resistor element and is configured, in the event of an insulation fault, to generate a current above the sensitivity threshold by virtue of the resistance value of the resistor element corresponding to the value of 80 kOhm with a deviation of not more than 20% or 10%, and the high-voltage vehicle on-board electrical system having a nominal voltage of 800 V.

5. The high-voltage vehicle on-board electrical system of claim 1, wherein the dissipating element comprises a resistor element and the dissipating element is configured, in the event of an insulation fault, to generate a current above the sensitivity threshold by virtue of the resistance value of the resistor element corresponding to the value of 40 kOhm with a deviation of not more than 20% or 10%, and the high-voltage vehicle on-board electrical system having a nominal voltage of 400 V.

6. The high-voltage vehicle on-board electrical system of claim 1, which also has an insulation monitor that monitors the insulation of the high-voltage potential from the ground potential.

7. The high-voltage vehicle on-board electrical system of claim 5, wherein the insulation monitor is configured to actively monitor the insulation by applying a test voltage or by injecting a test current.

8. The high-voltage vehicle on-board electrical system of claim 1, further comprising:
a first Cy capacitor connecting the potential island to the high-voltage potential; and
a second Cy capacitor connects the potential island to the ground potential.

9. The high-voltage vehicle on-board electrical system of claim 7, wherein the Cy capacitors each have a capacitance of at least 100 pF, 500 pF or 700 pF and of not more than 50 nF, 20 nF, 10 nF, 5 nF or 2 nF.

10. The high-voltage vehicle on-board electrical system of claim 1, wherein the insulation devices are provided as insulation barriers of optocouplers, transformers and/or cable insulation.

11. A DC voltage charging section of an electric drivetrain of a vehicle comprising the high-voltage vehicle on-board electrical system of claim 1.
